(19) United States
(12) Patent Application Publication
(10) Pub. No.: US 2025/0098349 A1
(43) Pub. Date: Mar. 20, 2025

(54) IMAGE SENSORS HAVING GRID STRUCTURE

(71) Applicant: SAMSUNG ELECTRONICS CO., LTD., Suwon-si (KR)

(72) Inventors: Wonchun YANG, Suwon-si (KR); Jaekwan Seo, Suwon-si (KR); Kwonseok Kim, Suwon-si (KR); Ryunhwa Lee, Suwon-si (KR)

(73) Assignee: SAMSUNG ELECTRONICS CO., LTD., Suwon-si (KR)

(21) Appl. No.: 18/734,474

(22) Filed: Jun. 5, 2024

(30) Foreign Application Priority Data
Sep. 19, 2023 (KR) 10-2023-0124894

(51) Int. Cl. H01L 27/146

(52) U.S. Cl. CPC H10F 39/8053; H10F 39/024; H10F 39/182; H10F 39/8063; H10F 39/807; H10F 39/809

(57) ABSTRACT

An image sensor may include photoelectric conversion elements within a substrate, a separation structure within the substrate and between the photoelectric conversion elements, an insulating structure on the substrate and the separation structure, a plurality of color filters on the insulating structure, a grid structure including a lower horizontal structure disposed on the insulating structure and a vertical structure connected to the lower horizontal structure and covering a side surface of one of the plurality of color filters, upper horizontal structures covering upper surfaces of the plurality of color filters, and a capping layer covering the upper horizontal structures and the grid structure. The grid structure may further include an air gap surrounded by the vertical structure, the lower horizontal structure, and the capping layer.

### CROSS-REFERENCE TO RELATED APPLICATION

This application claims priority to Korean Patent Application No. 10-2023-0124894 filed on Sep. 19, 2023, in the Korean Intellectual Property Office, the disclosure of which is incorporated by reference herein in its entirety.

### BACKGROUND

The present disclosure relates generally to an image sensor including a grid structure.

An image sensor is a semiconductor-based sensor which may receive light and generate an electrical signal, and may include a pixel array having a plurality of pixels, a logic circuit for driving the pixel array and generating an image, and the like. Each of the pixels may include a photo diode and a pixel circuit which may convert charges generated by the photo diode into an electrical signal.

### SUMMARY

One or more example embodiments provide an image sensor including a grid structure including an air gap.

According to example embodiments, an image sensor may include photoelectric conversion elements within a substrate; a separation structure within the substrate and between the photoelectric conversion elements; an insulating structure on the substrate and the separation structure; a plurality of color filters on the insulating structure; a grid structure including a lower horizontal structure disposed on the insulating structure and a vertical structure connected to the lower horizontal structure and covering a side surface of one of the plurality of color filters; upper horizontal structures covering upper surfaces of the plurality of color filters; and a capping layer covering the upper horizontal structures and the grid structure. The grid structure may further include an air gap surrounded by the vertical structure, the lower horizontal structure, and the capping layer.

According to example embodiments, an image sensor may include photoelectric conversion elements within a substrate; a separation structure within the substrate and between the photoelectric conversion elements; an insulating structure on the substrate and the separation structure; a plurality of color filters on the insulating structure; a protective layer covering the insulating structure and the plurality of color filters; and a capping layer covering the protective layer. A lower end of the capping layer may be at a level higher than lower surfaces of the plurality of color filters, and the protective layer and the capping layer define an air gap between the plurality of color filters.

According to example embodiments, an image sensor may include a lower chip including a logic circuit; and an upper chip on the lower chip, bonded to the lower chip. The upper chip may include photoelectric conversion elements disposed within a substrate; a separation structure disposed within the substrate and between the photoelectric conversion elements; an insulating structure disposed on the substrate and the separation structure; a plurality of color filters disposed on the insulating structure and spaced apart from each other; a grid structure disposed between the plurality of color filters, the grid structure including a lower horizontal structure disposed on the insulating structure and a vertical structure connected to the lower horizontal structure and covering a side surface of one of the plurality of color filters; upper horizontal structures covering upper surfaces of the plurality of color filters; a capping layer covering the upper horizontal structures and the grid structure; and a micro lens disposed on the capping layer. The grid structure may include an air gap surrounded by the vertical structure, the lower horizontal structure, and the capping layer.

### BRIEF DESCRIPTION OF DRAWINGS

The above and other aspects and features will be more apparent from the following detailed description of one or more example embodiments, taken in conjunction with the accompanying drawings, in which:

FIG. 1 is a block diagram briefly illustrating an image sensor according to one or more example embodiments;

FIG. 2A is a diagram schematically illustrating illustrative examples of a pixel circuit of an image sensor according to one or more example embodiments;

FIG. 2B is a diagram schematically illustrating illustrative examples of a pixel circuit of an image sensor according to one or more example embodiments;

FIG. 3 is a plan view schematically illustrating an image sensor according to one or more example embodiments;

FIG. 4 is an enlarged view of the image sensor illustrated in FIG. 3;

FIG. 5 is a vertical cross-sectional view taken along line I-I′ of the image sensor illustrated in FIG. 4;

FIG. 6 is an enlarged view of the image sensor illustrated in FIG. 5;

FIG. 7 is a vertical cross-sectional view taken along line II-II′ of the image sensor illustrated in FIG. 4;

FIG. 8 is a vertical cross-sectional view illustrated in process order with FIGS. 9 to 12 to describe a method of manufacturing an image sensor according to one or more example embodiments;

FIG. 9 is a vertical cross-sectional view illustrated in process order with FIGS. 8 and 10 to 12 to describe a method of manufacturing an image sensor according to one or more example embodiments;

FIG. 10 is a vertical cross-sectional view illustrated in process order with FIGS. 8, 9, 11 and 12 to describe a method of manufacturing an image sensor according to one or more example embodiments;

FIG. 11 is a vertical cross-sectional view illustrated in process order with FIGS. 8 to 10 and 12 to describe a method of manufacturing an image sensor according to one or more example embodiments;

FIG. 12 is a vertical cross-sectional view illustrated in process order with FIGS. 8 to 11 to describe a method of manufacturing an image sensor according to one or more example embodiments;

FIG. 13 is a vertical cross-sectional view of an image sensor according to one or more example embodiments;

FIG. 14 is a vertical cross-sectional view of an image sensor according to one or more example embodiments;

FIG. 15 is a vertical cross-sectional view of an image sensor according to one or more example embodiments;

FIG. 16 is a vertical cross-sectional view of an image sensor according to one or more example embodiments;

FIG. 17 is a vertical cross-sectional view of an image sensor according to one or more example embodiments;

FIG. 18 is a vertical cross-sectional view of an image sensor according to one or more example embodiments;

FIG. 19 is a vertical cross-sectional view of an image sensor according to one or more example embodiments; and

FIG. 20 is a vertical cross-sectional view of an image sensor according to one or more example embodiments.

### DETAILED DESCRIPTION

Hereinafter, one or more example embodiments of the technical idea of the inventive concept will be described in detail with reference to the accompanying drawings. The same reference numerals are used for the same components in the drawings, and duplicate descriptions thereof are omitted.

According to one or more example embodiments, terms such as ‘on’, ‘upper portion’, ‘upper surface’, ‘below’, ‘lower portion’, ‘lower surface’, ‘bottom’, ‘side surface’, ‘upper end’, ‘lower end’ and the like are indicated with reference numerals, and may be understood that reference is made based on the drawings unless otherwise indicated. It should also be understood that these terms are relative to each other, and do not indicate a position of components with respect to the direction of gravity. Further, ‘surround’ may mean that one component is completely surrounded by another component or the one component is partially surrounded another component. Furthermore, in embodiments, surround may describe an orientation or arrangement of components along a certain axis or a certain cross sectional view.

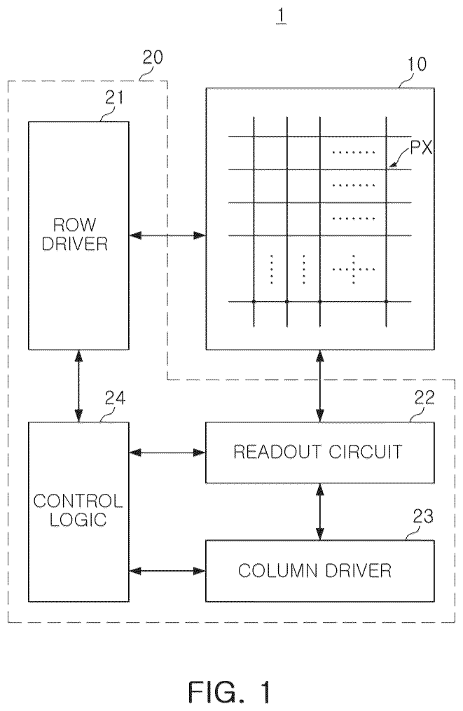

First, with reference to FIG. 1, an illustrative example of an image sensor according to one or more example embodiments will be described. FIG. 1 is a simple block diagram of an image sensor according to one or more example embodiments.

Referring to FIG. 1, the image sensor 1 may include a pixel array 10 and a logic circuit 20. The pixel array 10 may include a plurality of pixels PX arranged in an array along a plurality of rows and a plurality of columns. Each of the plurality of pixels PX may include at least one photoelectric conversion element that generates charge in response to light, and a pixel circuit that generates a pixel signal corresponding to the charge generated by the photoelectric conversion element. The photoelectric conversion element may include a photodiode formed of a semiconductor material, and/or an organic photodiode formed of an organic material.

For example, the pixel circuit may include a floating diffusion, a transfer transistor, a reset transistor, a driving transistor, and a selection transistor. The configuration of the pixels PX may vary depending on embodiments. For example, each of the pixels PX may include an organic photo diode containing an organic material, or may be implemented as a digital pixel. When the pixels PX are implemented as digital pixels, each of the pixels PX may include an analog-to-digital converter for outputting a digital pixel signal.

The logic circuit 20 may include circuits for controlling the pixel array 10. For example, the logic circuit 20 may include a row driver 21, a readout circuit 22, a column driver 23, and control logic 24. The row driver 21 may drive the pixel array 10 in units of row lines. For example, the row driver 21 generates a transmission control signal for controlling the transfer transistor of the pixel circuit, a reset control signal for controlling the reset transistor, and a selection control signal for controlling the selection transistor, and may input the signals to the pixel array 10 in row line units.

The readout circuit 22 may include a correlated double sampler CDS, an analog-to-digital converter ADC, etc. The correlated double samplers may be connected to the pixels PX through column lines. The correlated double samplers may read pixel signals through column lines from the pixels PX connected to the row line selected by the row line selection signal of the row driver 21. The analog-to-digital converter may convert the pixel signal detected by the correlated double sampler into a digital pixel signal and transmit it to the column driver 23.

The column driver 23 may include a latch or buffer circuit capable of temporarily storing a digital pixel signal, an amplifier circuit, etc., and may process the digital pixel signal received from the readout circuit 22. The row driver 21, the readout circuit 22, and the column driver 23 may be controlled by the control logic 24. The control logic 24 may include a timing controller for controlling the operation timing of the row driver 21, the readout circuit 22, and the column driver 23.

Among the pixels PX, pixels PX disposed at the same position in the horizontal direction may share the same column line. In an example, pixels PX arranged at the same position in the vertical direction may be simultaneously selected by the row driver 21 and output a pixel signal through column lines. In an example, the readout circuit 22 may simultaneously obtain pixel signals from the pixels PX selected by the row driver 21 through column lines. The pixel signal may include a reset voltage and a pixel voltage, and the pixel voltage may be a voltage in which charges generated in response to light in each of the pixels PX are reflected in the reset voltage.

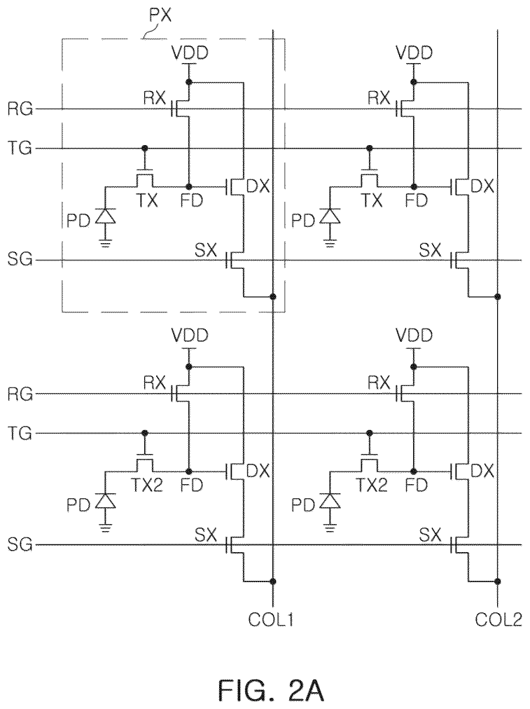

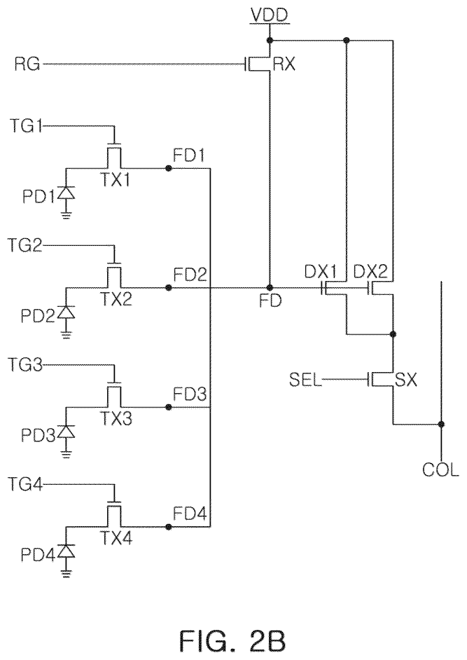

Next, various examples of a pixel circuit of an image sensor according to one or more example embodiments will be described with reference to FIGS. 2A and 2B, respectively. 2A and 2B are diagrams briefly illustrating illustrative examples of a pixel circuit of an image sensor according to one or more example embodiments.

In an example, referring to FIGS. 1 and 2A, each of the plurality of pixels PX may include a photo diode PD and a pixel circuit, and the pixel circuit may include a transfer transistor TX, a reset transistor RX, a selection transistor SX, and a driving transistor DX.

The photodiode PD may generate and accumulate charges in response to light incident from the outside. The pixel circuit may further include a floating diffusion region FD in which charges generated in the photo diode PD are accumulated.

The photo diode PD may be replaced with a photo transistor, photo gate, or pinned photo diode, depending on embodiments. The photo diode PD may be referred to and described as a “photoelectric conversion element.” Accordingly, the photoelectric conversion element may be a photodiode, phototransistor, photogate, or pinned photodiode.

The transfer transistor TX may move charges generated in the photodiode PD to the floating diffusion region FD. The floating diffusion region FD may store charges generated in the photo diode PD. The voltage output by the driving transistor DX may vary depending on the amount of charge accumulated in the floating diffusion region FD.

The reset transistor RX may reset the voltage of the floating diffusion region FD by removing charges accumulated in the floating diffusion region FD. The drain electrode of the reset transistor RX may be connected to the floating diffusion region FD, and the source electrode may be connected to the power supply voltage VDD. When the reset transistor RX is turned on, the power supply voltage VDD connected to the source electrode of the reset transistor RX is applied to the floating diffusion region FD, and charges accumulated in the floating diffusion region FD may be removed.

The driving transistor DX may operate as a source follower buffer amplifier. The driving transistor DX may amplify the voltage change in the floating diffusion region FD and output this to one of the column lines COL1 and COL2. The selection transistor SX may select pixels PX to be read row by row. When the selection transistor SX is turned on, the voltage of the driving transistor DX may be output to one of the column lines COL1 and COL2. When the selection transistor SX is turned on, a reset voltage or a pixel voltage may be output through the column lines COL1 and COL2.

In one or more example embodiments illustrated in FIG. 2A, each of the plurality of pixels PX may include all of the photodiode PD and the transfer transistor TX, as well as the reset transistor RX, the selection transistor SX, and the driving transistor DX. The embodiment(s) is not limited to this and may be modified as illustrated in FIG. 2B.

In a modified example, referring to FIGS. 1 and 2B, two or more pixels adjacent to each other may share at least some of the transistors included in the pixel circuit. For example, four pixels adjacent to each other may share one floating diffusion region FD, a reset transistor RX, first and second driving transistors DX1 and DX2, and a selection transistor SX.

In an example, the first photo diode PD1 and the first transfer transistor TX1 of the first pixel may be connected to the floating diffusion region FD. Likewise, the second to fourth photodiodes PD2-PD4 of the second to fourth pixels may be connected to the floating diffusion region FD through the second to fourth transfer transistors TX2-TX4.

In an example, the floating diffusion regions FD included in each pixel may be connected to each other using an interconnection pattern, etc., so that the first to fourth transfer transistors TX1-TX4 are common to one floating diffusion region FD.

In another example, the floating diffusion region FD included in each pixel may be formed as one within a substrate that may be formed of a semiconductor material.

The pixel circuit may include the reset transistor RX, the first and second driving transistors DX1 and DX2, and the selection transistor SX. The reset transistor RX may be controlled by a reset control signal RG, and the selection transistor SX may be controlled by a selection control signal SEL. For example, each of the four pixels may further include one transistor in addition to the transfer transistor TX. Among the four transistors included in the four pixels, two are connected in parallel to provide the first and second driving transistors DX1 and DX2, and one of the remaining two transistors serves as the select transistor SX, and the other one may be configured to provide the reset transistor RX.

The pixel circuit described with reference to FIG. 2B is only an example and is not necessarily limited to this form. For example, one of the four transistors may be assigned as a driving transistor and one may be assigned as a selection transistor. Additionally, by connecting the remaining two in series and assigning them to the first and second reset transistors, an image sensor that may adjust the conversion gain of the pixel may be implemented. Alternatively, the pixel circuit may vary depending on the number of transistors included in each pixel. As such, the pixel circuits described with reference to FIGS. 2A and 2B are illustrative examples for implementing an image sensor according to one or more example embodiments, and the embodiment is not limited thereto.

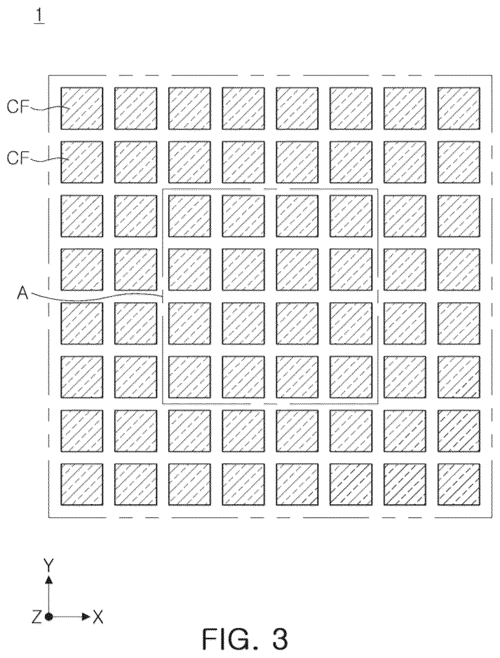

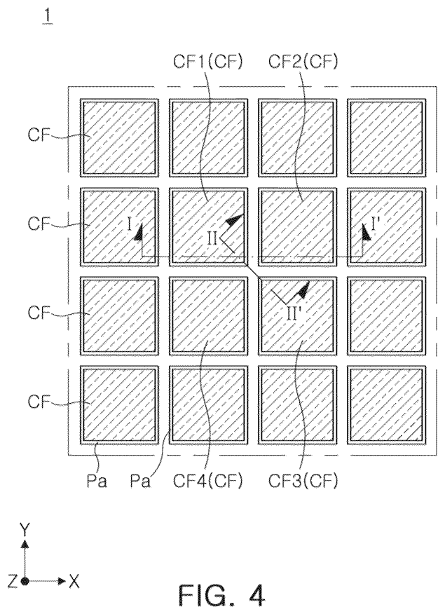

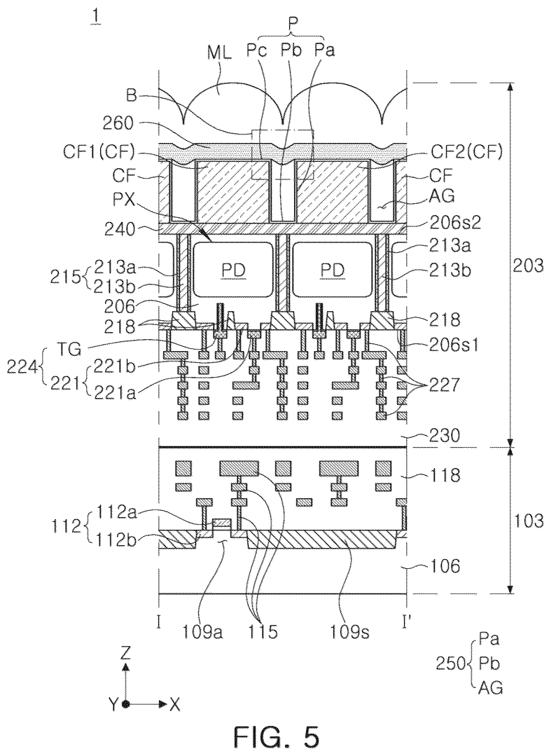

Next, with reference to FIGS. 3 to 5, an example of an image sensor structure according to one or more example embodiments will be described. FIGS. 3 to 5 are diagrams schematically illustrating an image sensor according to one or more example embodiments. FIG. 3 is a plan view schematically illustrating an image sensor according to one or more example embodiments, FIG. 4 is an enlarged view of the image sensor illustrated in FIG. 3, and FIG. 5 is a vertical cross-sectional view along line I-I′ of the image sensor illustrated in FIG. 4.

Referring to FIGS. 3 to 5, the image sensor 1 according to the embodiment(s) may have a stacked chip structure using at least two chips. For example, the image sensor 1 may include a first chip structure 103 and a second chip structure 203 on the first chip structure 103. The first chip structure 103 may be a logic chip, and the second chip structure 203 may be an image sensor chip. In another example, the first chip structure 103 may be a stacked chip structure including a logic chip and a memory chip.

The first chip structure 103 of the image sensor 1 may include a first substrate 106, a device isolation film 109s defining the active region 109a on the first substrate 106, a first circuit element 112 and a first interconnection structure 115 on the first substrate 106, and a first insulating structure 118 covering the first circuit element 112 and the first interconnection structure 115 on the first substrate 106.

The first substrate 106 may be a semiconductor substrate. For example, the first substrate 106 may be a substrate formed of a semiconductor material, for example, a single crystal silicon substrate. The first circuit element 112 may include an element such as a transistor including a gate 112a and a source/drain 112b.

The second chip structure 203 may include a second substrate 206 having a first surface 206s1 and a second surface 206s2 facing each other, an isolation film 218 disposed on the first surface 206s1 of the second substrate 206 and defining an active area, a second circuit element 224 and a second interconnection structure 227 disposed between the first surface 206s1 of the second substrate 206 and the first chip structure 103, and a second insulating structure 230 covering the second circuit element 224 and the second interconnection structure 227 between the first surface 206s1 of the second substrate 206 and the first chip structure 103. The first surface 206s1 of the second substrate 206 may face the first chip structure 103. The device isolation film 218 may be formed of an insulating material such as silicon oxide. The second circuit element 224 and the second interconnection structure 227 disposed below the first surface 206s1 of the second substrate 206 may form a circuit interconnection structure. Accordingly, a circuit interconnection structure may be disposed below the first surface 206s1 of the second substrate 206.

The second substrate 206 may be a semiconductor substrate. For example, the second substrate 206 may be a substrate formed of a semiconductor material, for example, a single crystal silicon substrate.

The image sensor 1 may further include a plurality of pixel areas PX disposed within the second substrate 206. The pixel area PX may correspond to the pixel PX described above with reference to FIGS. 1 to 2B. Each of the plurality of pixel areas may include photoelectric conversion elements PD. The photoelectric conversion elements PD may generate and accumulate charges corresponding to incident light. For example, the photoelectric conversion elements PD may include a photo diode, a photo transistor, a photo gate, a pinned photo diode (PPD), and combinations thereof.

Each of the photoelectric conversion elements PD may be a photodiode that may be formed in the second substrate 206. Accordingly, each of the plurality of pixel areas may include a photo diode. The plurality of pixel areas may each be referred to as photoelectric conversion elements PD or photodiodes.

The second chip structure 203 may further include a separation structure 215. The separation structure 215 may be arranged to surround each of the photoelectric conversion elements PD. The separation structure 215 may vertically penetrate at least a portion of the second substrate 206. For example, the separation structure 215 may vertically penetrate the second substrate 206. The separation structure 215 may be disposed in the separation trench 212 that vertically penetrates the second substrate 206. The separation structure 215 may be connected to the device isolation film 218. Accordingly, the separation structure 215 may penetrate the second substrate 206 between the device isolation film 218 and the second surface 206s2 of the second substrate 206. The separation structure 215 may have substantially vertical sides.

The separation structure 215 may include a separation pattern 213b and a separation insulating layer 213a covering a side surface of the separation pattern 213b. For example, the isolation insulating layer 215a may include silicon oxide, and the separation pattern 213b may include polysilicon. The separation pattern 213b may also be referred to as a silicon pattern or poly-silicon pattern. The separation insulating layer 213a may be formed of a single material layer.

The separation pattern 213b may be formed of a material capable of applying a voltage to the separation pattern 213b in order to significantly reduce or prevent interference or influence between the photoelectric conversion elements PD. For example, the separation pattern 213b may include a conductive material, for example, doped polysilicon. In an example, the separation pattern 213b may be formed of doped polysilicon having an N-type conductivity type. In another example, the separation pattern 213b may be formed of doped polysilicon having a P-type conductivity type.

The second circuit element 224 may include a transfer gate TG and active elements 221. The active elements 221 may be transistors including a gate 221a and source/drain 221b. The transfer gate TG may transfer charge from an adjacent photoelectric conversion element PD to an adjacent floating diffusion region. The active elements 221 may be various transistors of the pixel circuit described in FIGS. 2A and 2B, for example, a driving transistor, a reset transistor, and a selection transistor.

The transfer gate TG may be a vertical transfer gate including a portion extending from the first surface 206s1 of the second substrate 206 into the inside of the second substrate 206.

The second interconnection structure 227 may include a multilayer wire located at different height levels and vias that electrically connect the multilayer wires and electrically connect the multilayer wires to the second circuit element 224.

The first insulating structure 118 and the second insulating structure 230 may contact and be bonded to each other. Each of the first and second insulating structures 118 and 230 may be formed of multiple layers including different types of insulating layers. For example, the second insulating structure 230 may be formed of multiple layers including at least two types of a silicon oxide layer, a low dielectric layer, and a silicon nitride layer.

The second chip structure 203 may further include an insulating structure 240 disposed on the second surface 206s2 of the second substrate 206. The insulating structure 240 may cover the separation structure 215.

The insulating structure 240 may include an anti-reflection layer that may prevent reflection of light that may occur due to a sudden change in refractive index on the second surface 206s2 of the second substrate 206, which may be formed of silicon. The insulating structure 240 may include an anti-reflection layer that may adjust the refractive index to allow incident light to proceed to the photoelectric conversion elements PD with high transmittance. The insulating structure 240 may also be referred to as an anti-reflection structure or an anti-reflection layer.

The insulating structure 240 may have transparency at visible wavelengths and may include a material with a negative charge to prevent charge due to dangling bonds on the second surface 206s2 of the substrate 206. Additionally, the insulating structure 240 may include a material that may adjust the peak of transmittance by adjusting the thickness. The insulating structure 240 may include at least one of silicon oxide, aluminum oxide, and hafnium oxide. The insulating structure 240 may be formed of a single layer or multiple layers.

The second chip structure 203 may include color filters CF. For example, the color filters CF may include color filters CF that filter different colors. For example, the color filters CF may include at least one of green color filters, blue color filters, red color filters, white color filters, and yellow color filters.

The color filters CF may be disposed on the insulating structure 240. The color filters CF may vertically overlap the corresponding photoelectric conversion elements PD. The color filters CF may allow light of a specific wavelength to pass through and reach the photoelectric conversion elements PD. For example, the color filters CF may be formed of a material that mixes resin with a pigment containing metal or metal oxide.

In one or more example embodiments, the color filters CF may have a rectangular shape when viewed in plan view. Color filters CF configured to filter the same color may be referred to as a filter group. In one or more example embodiments, the plurality of filter groups may each be arranged in a 2×2 array. In some embodiments, the plurality of filter groups may each be arranged in a 1×1 array or a 3×3 array.

The second chip structure 203 may further include a protective layer P. The protective layer P may be disposed on the insulating structure 240 and the color filters CF. For example, the protective layer P may cover the insulating structure 240 and the color filters CF, and may be conformally disposed along the surfaces of the insulating structure 240 and the color filters CF. In one or more example embodiments, the protective layer P may include a vertical structure Pa, a lower horizontal structure Pb, and an upper horizontal structure Pc. For example, a portion of the protective layer P that covers the insulating structure 240 and extends in the horizontal direction may be referred to as the lower horizontal structure Pb. A portion of the protective layer P extending in the vertical direction and covering the side surface of the color filter CF may be referred to as a vertical structure Pa. A portion of the protective layer P that covers the upper surface of the color filter CF and extends in the horizontal direction may be referred to as the upper horizontal structure Pc.

The vertical structure Pa, the lower horizontal structure Pb, and the upper horizontal structure Pc may be connected to each other and may be formed integrally. In a top view, each color filter CF may be surrounded by vertical structures Pa. The lower horizontal structures Pb may extend in the horizontal direction between the color filters CF. The thickness Tp of the protective layer P may be about 3 nm to about 200 nm. For example, the thickness Tp of each of the vertical structure Pa, the lower horizontal structure Pb, and the upper horizontal structure Pc may be from about 3 nm to about 200 nm.

The protective layer P may include at least one of silica (SiO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), oxide Cerium (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (HO₂O₃), thulium oxide (Tm₂O₃), ytterbium oxide (Yb₂O₃), lutetium oxide (Lu₂O₃), or yttrium oxide (Y₂O₃).

The vertical structures Pa arranged adjacent to each other and the lower horizontal structure Pb between them may form a grid structure 250. In one or more example embodiments, the grid structure 250 may vertically overlap the separation structure 215. In one or more example embodiments, the grid structure 250 may have a different width than the separation structure 215. For example, the width of the grid structure 250 may be larger than the width of the separation structure 215. The grid structure 250 may extend in the horizontal direction between the color filters CF. In one or more example embodiments, the grid structure 250 may be disposed between the color filters CF. The thickness of each of the color filters CF may be greater than the thickness of the grid structure 250. The color filters CF may cover a side of the grid structure 250 on the insulating structure 240. In plan view, each color filter CF may be surrounded by a vertical structure Pa.

The second chip structure 203 may further include a capping layer 260. The capping layer 260 may be disposed on the color filters CF. For example, the capping layer 260 may cover the upper horizontal structures Pc on the color filters CF, and the space between the color filters CF may be sealed. The enclosed space may be referred to as an air gap AG. For example, the grid structure 250 may include an air gap AG therein. The lower end of the capping layer 260 may be disposed at a higher level than the lower surface of the color filters CF. The capping layer 260 may not be in direct contact with the color filters CF, and may be arranged to be spaced apart from the color filters CF with the protective layer P interposed therebetween. The capping layer 260 may include a different material from the protective layer P. In one or more example embodiments, the capping layer 260 may include a transparent insulating material. For example, the capping layer 260 may include an organic material.

The lower horizontal structure Pb, the vertical structure Pa, and the capping layer 260 may define an air gap AG, i.e., the lower horizontal structure Pb, the vertical structure Pa, and the capping layer 260 are disposed around the air gap. The upper limit of the air gap AG may be defined by the capping layer 260, the lateral limit of the air gap AG may be defined by the vertical structures Pa, and the air gap AG may be defined by the lower horizontal structure Pb. Since the grid structure has an air gap AG with a refractive index of 1 inside, the optical cross-talk of the image sensor 1 may be prevented or reduced. In the top view, the air gap AG may extend horizontally along the grid structure 250 between the color filters CF.

Among the plurality of color filters CF, four color filters CF adjacent to each other may be referred to as a first color filter CF1, a second color filter CF2, a third color filter CF3, and a fourth color filter CF4, respectively. The second color filter CF2 may be spaced apart from the first color filter CF1 in the X direction and may be spaced apart from the third color filter CF3 in the Y direction. The fourth color filter CF4 may be spaced apart from the first color filter CF1 in the Y direction and may be spaced apart from the third color filter CF3 in the X direction.

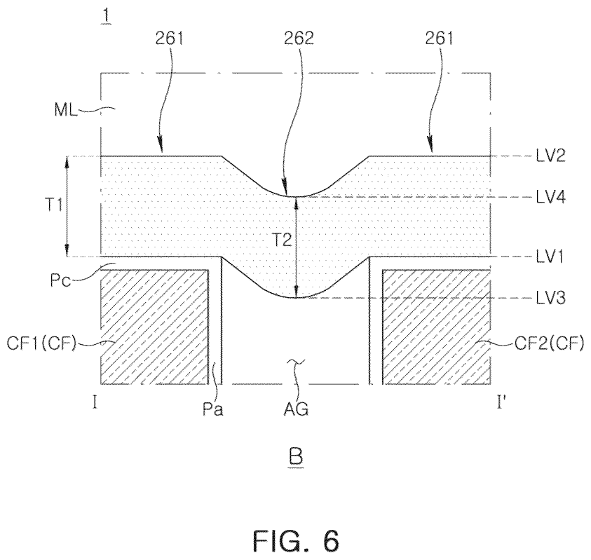

FIG. 6 is an enlarged view of the image sensor illustrated in FIG. 5.

Referring further to FIG. 6, the grid structure 250 may be disposed between two adjacent color filters CF, for example, between the first color filter CF1 and the second color filter CF2. The capping layer 260 may cover the grid structure 250. The capping layer 260 may include a first portion 261 and a second portion 262. For example, a portion of the capping layer 260 that vertically overlaps the color filter CF may be referred to as a first portion 261. A portion of the capping layer 260 that is disposed between two adjacent color filters CF and does not vertically overlap the color filters CF may be referred to as a second portion 262. In some embodiments, the upper and lower surfaces of the second portion 262 may be convex or concave, respectively. In one or more example embodiments, the upper and lower surfaces of the second portion 262 may each be flat. In some embodiments, at least a portion of the lower surface of the second portion 262 may be located at a different level from the lower surface of the first portion 261. In some embodiments, at least a portion of the upper surface of the second portion 262 may be located at a different level from the upper surface of the first portion 261.

The lower surface of the first portion 261 may be located at the first vertical level LV1, and the upper surface of the first portion 261 may be located at the second vertical level LV2. In one or more example embodiments, the second portion 262 of the capping layer 260 may be shifted lower than the first portion 261 and the upper and lower surfaces of the second portion 262 may be convex downwardly. For example, the lower end of the second portion 262 of the capping layer 260 may be located at a lower level than the lower end of the first portion 261. For example, the lower end of the lower surface of the second portion 262 may be located at the third vertical level LV3, and the third vertical level LV3 may be lower than the first vertical level LV1. In one or more example embodiments, the lower end of the upper surface of the second portion 262 of the capping layer 260 may be located at the fourth vertical level LV4, and the fourth vertical level LV4 may be lower than the second vertical level LV2.

In one or more example embodiments, the thickness T1 of the first portion 261 may be the same as the thickness T2 of the second portion 262, but is not limited thereto.

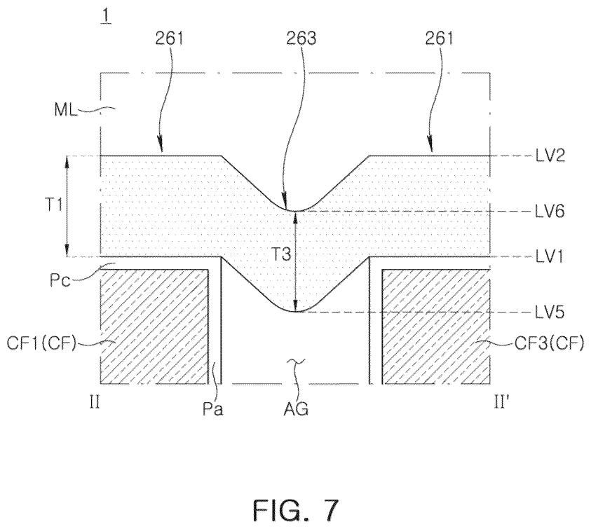

FIG. 7 is a vertical cross-sectional view taken along line II-II′ of the image sensor illustrated in FIG. 4. For convenience of explanation, FIG. 7 illustrates components disposed on the insulating structure 240, similar to FIG. 6.

Referring to FIG. 7, the capping layer 260 may further include a third portion 263. The third portion 263 may refer to a portion of the capping layer 260 disposed between four adjacent color filters CF, for example, between the first color filter CF1 and the third color filter CF3. In some embodiments, a portion of the lower surface of the third portion 263 may be located at a different level from the lower surface of the second portion 262. In some embodiments, a portion of the upper surface of the third portion 263 may be located at a different level from the upper surface of the third portion 263.

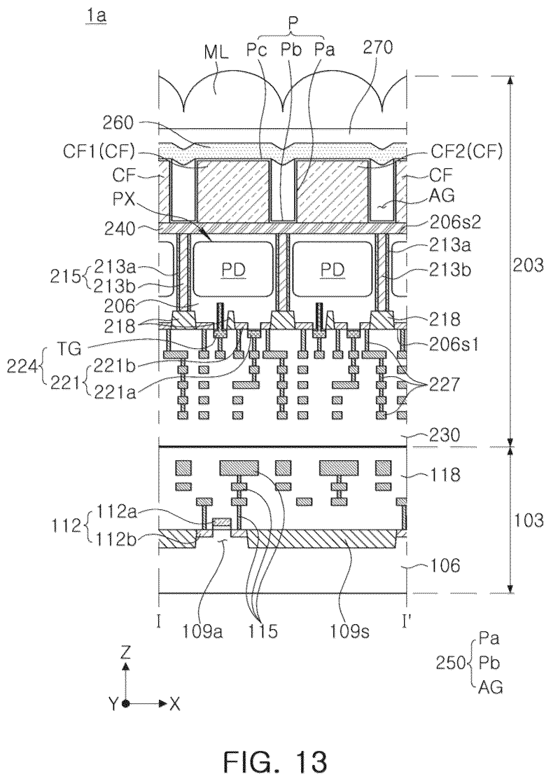

In one or more example embodiments, the third portion 263 of the capping layer 260 may be shifted lower than the second portion 262 and the upper and lower surfaces of the third portion 263 may be convex downwardly. For example, the lower end of the third portion 263 of the capping layer 260 may be located at a lower level than the lower end of the second portion 262. For example, the lower end of the lower surface of the third portion 263 may be located at the fifth vertical level LV5, and the fifth vertical level (LV5) may be lower than the third vertical level LV3. In one or more example embodiments, the lower end of the upper surface of the third portion 263 of the capping layer 260 may be located at the sixth vertical level LV6, and the sixth vertical level LV6 may be lower than the fourth vertical level LV4. The structural features of the lower surface of the third portion 263 of the capping layer 260 described above may also be applied to embodiments described with reference to FIGS. 13 to 15 and 18 described later.

In one or more example embodiments, the thickness T3 of the third portion 263 may be the same as the thickness T2 of the second portion 262, but is not limited thereto.

The second chip structure 203 may further include micro lenses ML on the capping layer 260.

The micro lenses ML may vertically overlap each of the color filters CF. In one or more example embodiments, the micro lenses ML may each vertically overlap the color filter CF. Alternatively, the micro lenses ML may vertically overlap each of the plurality of color filters CF. For example, one micro lens among the micro lenses ML may vertically overlap four adjacent color filters CF among the plurality of color filters CF.

Each of the micro lenses ML may have a convex shape in a direction away from the first chip structure 103. The micro lenses ML may converge incident light into the photoelectric conversion elements PD. The micro lenses ML may be formed of a transparent photoresist material or a transparent thermosetting resin material. For example, the microlenses ML may be formed of a TMR series resin (produced by Tokyo Ohka Kogo, Co.) or an MFR series resin (produced by Japan Synthetic Rubber Corporation), but one or more example embodiments are not limited to these substances.

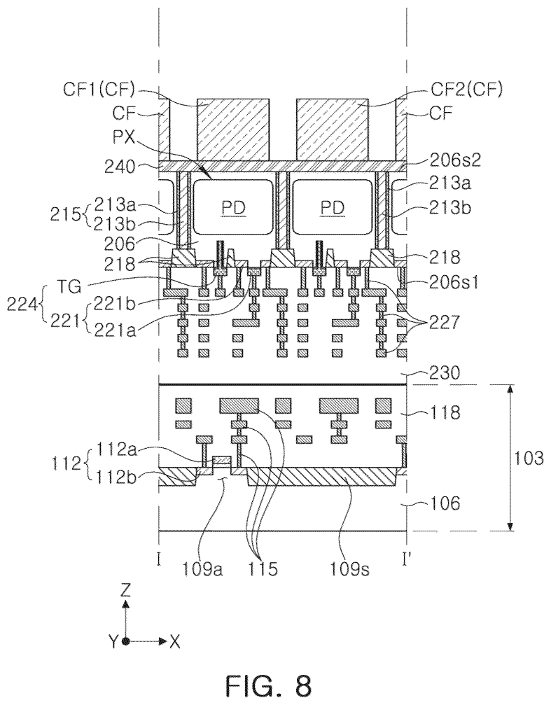

FIGS. 8. 9. 10. 11 and 12 are plan views and cross-sectional views illustrated in process order to describe a method of manufacturing an image sensor according to one or more example embodiments. In detail, FIGS. 8. 9. 10. 11 and 12B are vertical cross-sectional views corresponding to FIG. 5, respectively.

Referring to FIG. 8, color filters CF may be formed on the insulating structure 240. The color filters CF may be arranged to vertically overlap the photoelectric conversion elements PD. The color filters CF may be arranged to be spaced apart from each other in the X and Y directions.

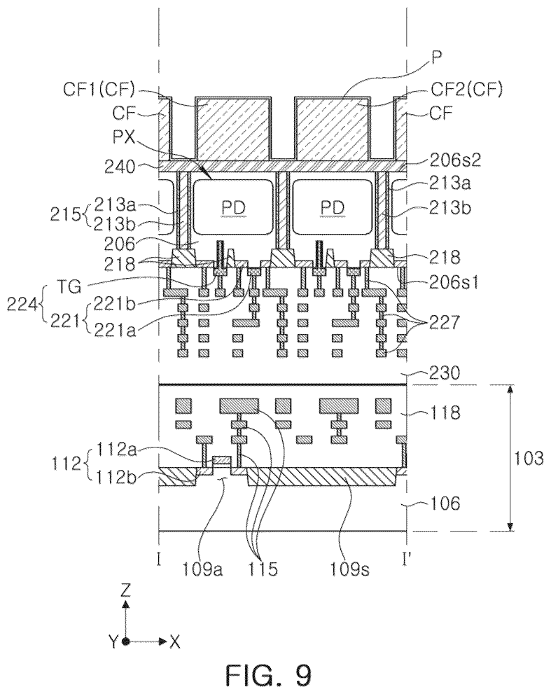

Referring to FIG. 9, a protective layer P may be formed. The protective layer P may cover the insulating structure 240 and the color filters CF. For example, the protective layer P may be formed conformally along the surfaces of the insulating structure 240 and the color filters CF.

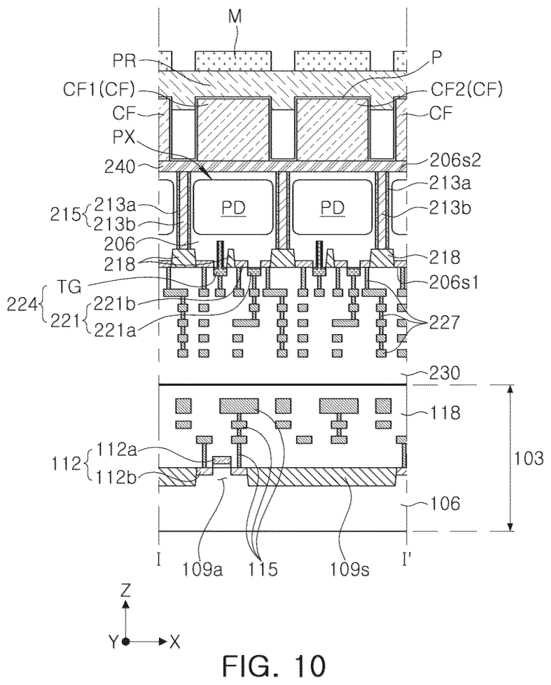

Referring to FIG. 10, a photo resist PR and a mask layer M may be formed on the protective layer P. The photo resist PR may cover the protective layer P, and a portion of the photo resist PR may be disposed between the color filters CF. The mask layer M may be disposed on the photo resist PR. The mask layer M may be patterned to expose a portion of the photo resist PR that vertically overlaps the separation structure 215.

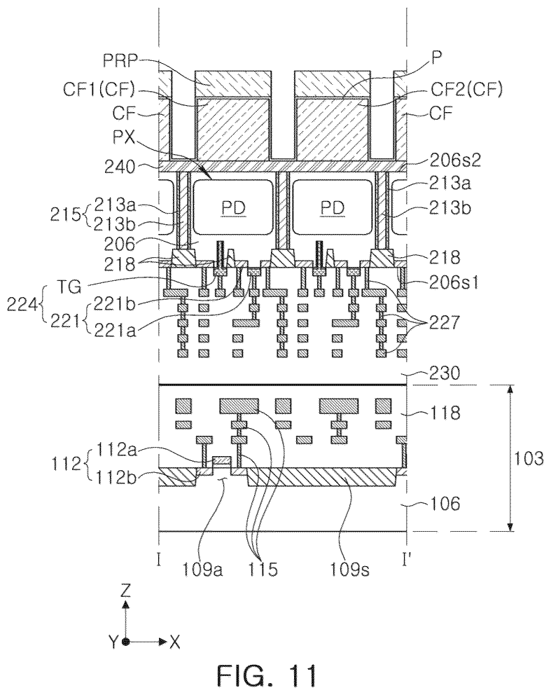

Referring to FIG. 11, an etching process may be performed using the mask layer M as an etch mask, and the photo resist PR may be patterned to form a photo resist pattern PRP. For example, a portion of the photo resist PR exposed by the mask layer M may be removed. The photoresist patterns PRP may be disposed on each of the color filters CF and may be disposed to be spaced apart from each other. After the etching process is performed, the mask layer M may be removed.

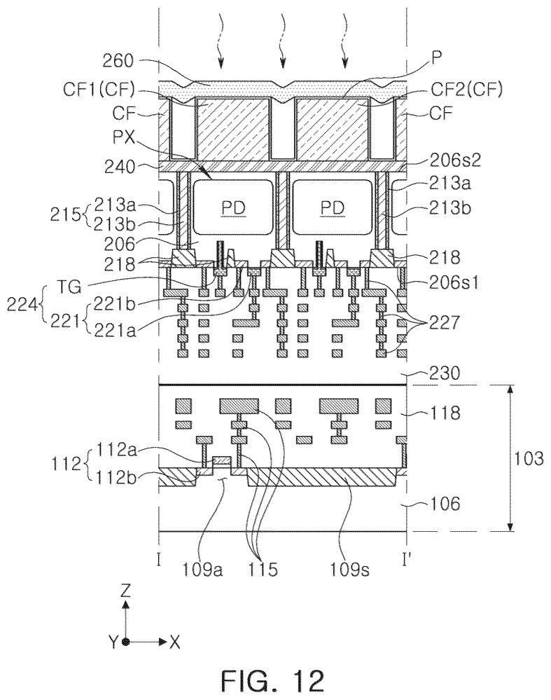

Referring to FIG. 12, a reflow process may be performed. For example, the photoresist patterns PRP may be heated and melted. The photoresist patterns PRP disposed on the color filters CF may be melted by heat and extended between the color filters CF to be combined with each other. The photo resist patterns PRP combined together may be referred to as a capping layer 260.

The capping layer 260 may include a first portion 261 that vertically overlaps the color filter CF and a second portion 262 disposed between two adjacent color filters CF. The second portion 262 may be formed by bonding adjacent photoresist patterns PRP together. In one or more example embodiments, the lower end of the second portion 262 may be located at a lower level than the lower surface of the first portion 261. However, the shape of the second portion 262 may vary depending on the viscosity and thickness of the capping layer 260, reflow process conditions, etc.

Referring again to FIG. 5, the image sensor 1 may be manufactured by forming a micro lens (ML) on the capping layer 260.

FIG. 13 is a vertical cross-sectional view of an image sensor according to one or more example embodiments.

Referring to FIG. 13, the image sensor 1a may include a capping layer 260 disposed on a grid structure 250 and color filters CF. In one or more example embodiments, the image sensor 1 may further include a capping layer 260 and a planarization layer 270 disposed on the micro lens ML. The planarization layer 270 may cover the upper surface of the capping layer 260. The planarization layer 270 may include an inorganic material or an organic material such as silicon oxide, silicon nitride, and silicon oxynitride.

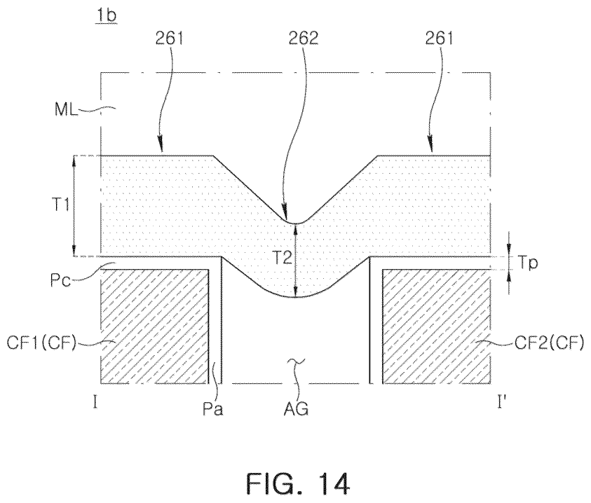

FIGS. 14 to 20 are vertical cross-sectional views of an image sensor according to one or more example embodiments.

Referring to FIG. 14, the image sensor 1b may include a grid structure 250 and a capping layer 260 disposed on color filters CF. The capping layer 260 may include a first portion 261 that vertically overlaps the color filter CF and a second portion 262 disposed between two adjacent color filters CF. In one or more example embodiments, the thickness T2 of the second portion 262 may be smaller than the thickness T1 of the first portion 261.

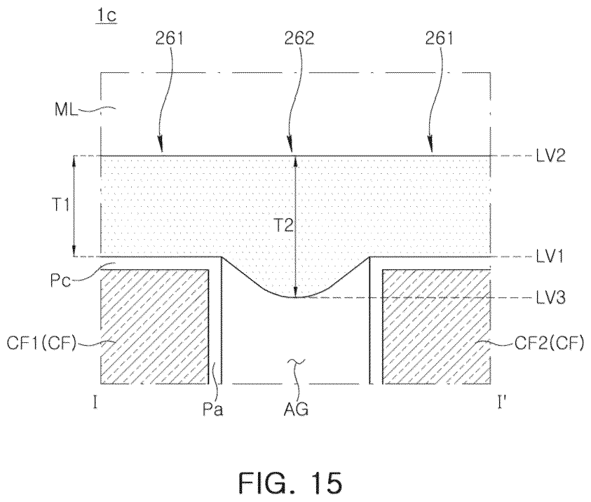

Referring to FIG. 15, the capping layer 260 of the image sensor 1c may include a first portion 261 that vertically overlaps the color filter CF, and a second portion 262 disposed between two color filters CF adjacent to each other. In one or more example embodiments, the upper surface of the second portion 262 may be coplanar with the upper surface of the first portion 261 and may be located at the same level. For example, the upper surface of the second portion 262 and the upper surface of the first portion 261 may be located at the second vertical level LV2. The lower end of the second portion 262 may be located at a lower level than the lower surface of the first portion 261. For example, the lower end of the second portion 262 may be located at the third vertical level LV3, which is lower than the first vertical level LV1. In one or more example embodiments, the thickness T2 of the second portion 262 may be greater than the thickness T1 of the first portion 261.

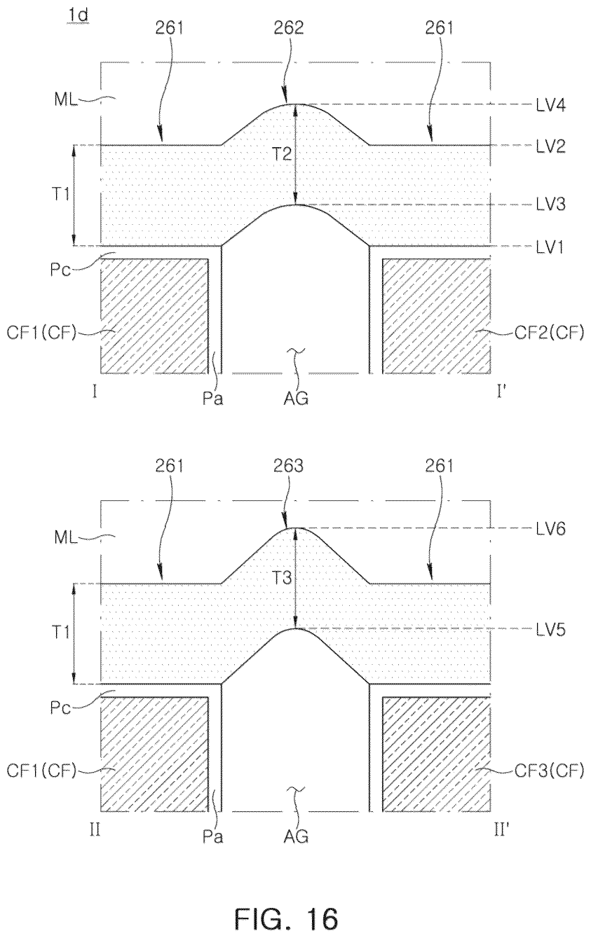

Referring to FIG. 16, the capping layer 260 of the image sensor 1d may include a first portion 261 that vertically overlaps the color filter CF and a second portion 262 disposed between two adjacent color filters CF. In one or more example embodiments, the second portion 262 of the capping layer 260 may be shifted above the first portion 261 and the upper and lower surfaces of the second portion 262 may be convex upwardly. For example, the upper end of the second portion 262 of the capping layer 260 may be located at a higher level than the lower end of the first portion 261. For example, the upper end of the lower surface of the second portion 262 may be located at the third vertical level LV3, and the third vertical level LV3 may be higher than the first vertical level LV1. In one or more example embodiments, the upper surface of the second portion 262 of the capping layer 260 may be located at the fourth vertical level LV4, and the fourth vertical level LV4 may be higher than the second vertical level LV2. The upper end of the air gap AG may be located at a higher level than the upper surface of the color filter CF.

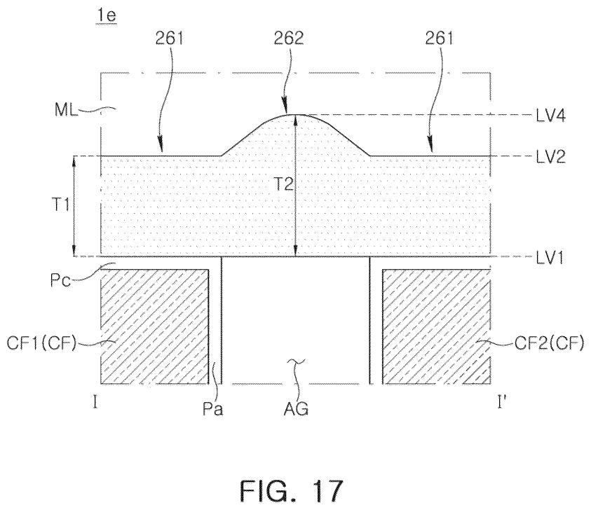

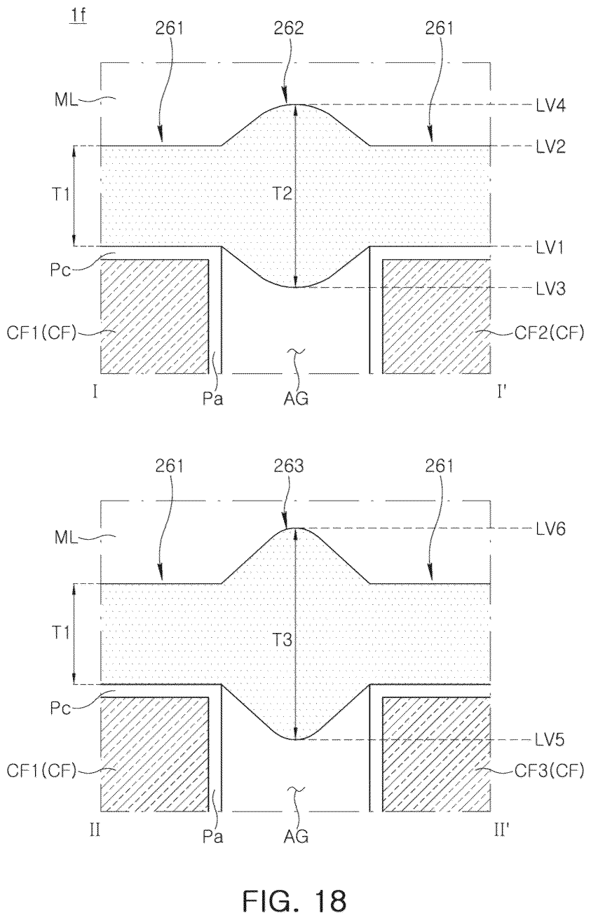

The capping layer 260 may also include a third portion 263 disposed between four adjacent color filters CF. In one or more example embodiments, the third portion 263 of the capping layer 260 may be shifted above the second portion 262 and the upper and lower surfaces of the third portion 263 may be convex upwardly. For example, the upper end of the third portion 263 of the capping layer 260 may be located at a higher level than the upper end of the second portion 262. For example, the upper end of the lower surface of the third portion 263 may be located at the fifth vertical level LV5, and the fifth vertical level LV5 may be higher than the third vertical level LV3. In one or more example embodiments, the upper surface of the third portion 263 of the capping layer 260 may be located at the sixth vertical level LV6, and the sixth vertical level (LV6) may be higher than the fourth vertical level LV4. In one or more example embodiments, the thickness T3 of the third portion 263 may be greater than or equal to the thickness T2 of the second portion 262. The structural features of the upper surface of the third portion 263 of the capping layer 260 described above may also be applied to embodiments described with reference to FIGS. 17 and 18 described later.

Referring to FIG. 17, the capping layer 260 of the image sensor 1e may include a first portion 261 that vertically overlaps the color filter CF and a second portion 262 disposed between two adjacent color filters CF. In one or more example embodiments, the lower surface of the second portion 262 may be coplanar with the lower surface of the first portion 261 and may be located at the same level. For example, the lower surface of the second portion 262 and the lower surface of the first portion 261 may be located at the first vertical level LV1. The upper end of the upper surface of the second portion 262 may be located at a higher level than the upper surface of the first portion 261. For example, the upper end of the upper surface of the second portion 262 may be located at the third vertical level LV3, which is higher than the first vertical level LV1. In one or more example embodiments, the thickness T2 of the second portion 262 may be greater than the thickness T1 of the first portion 261.

Referring to FIG. 18, the capping layer 260 of the image sensor If may include a first portion 261 that vertically overlaps the color filter CF and a second portion 262 disposed between two adjacent color filters CF. In one or more example embodiments, the upper surface of the second portion 262 may be convex upwardly, and the lower surface of the second portion 262 may be convex downwardly. The lower end of the lower surface of the second portion 262 may be located at a third vertical level LV3 lower than the first vertical level LV1, and the upper end of the upper surface of the second portion 262 may be located at the fourth vertical level LV4, which is higher than the second vertical level LV2. In one or more example embodiments, the thickness T2 of the second portion 262 may be greater than the thickness T1 of the first portion 261.

The capping layer 260 may also include a third portion 263 disposed between four adjacent color filters CF. In one or more example embodiments, the upper surface of the third portion 263 may be convex upwardly, and the lower surface of the third portion 263 may be convex downwardly. In one or more example embodiments, the thickness T3 of the third portion 263 may be greater than the thickness T2 of the second portion 262.

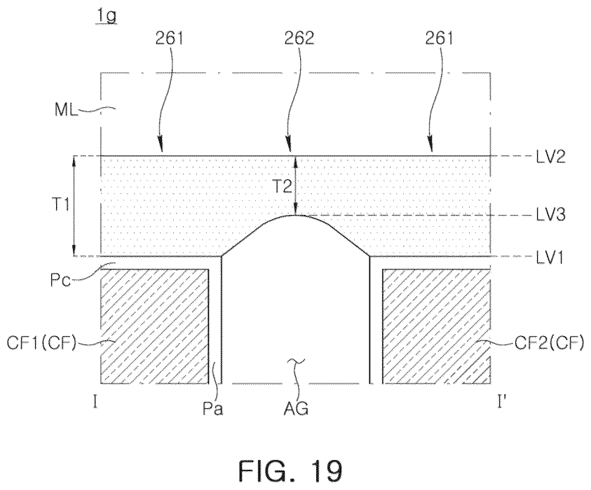

Referring to FIG. 19, the capping layer 260 of the image sensor 1g may include a first portion 261 that vertically overlaps the color filter CF and a second portion 262 disposed between two adjacent color filters CF. In one or more example embodiments, the upper surface of the second portion 262 may be coplanar with the upper surface of the first portion 261 and may be located at the same level. For example, the upper surface of the second portion 262 and the upper surface of the first portion 261 may be located at the second vertical level LV2. The upper end of the lower surface of the second portion 262 may be located at a higher level than the lower surface of the first portion 261. For example, the upper end of the lower surface of the second portion 262 may be located at the third vertical level LV3, which is higher than the first vertical level LV1. In one or more example embodiments, the thickness T2 of the second portion 262 may be smaller than the thickness T1 of the first portion 261.

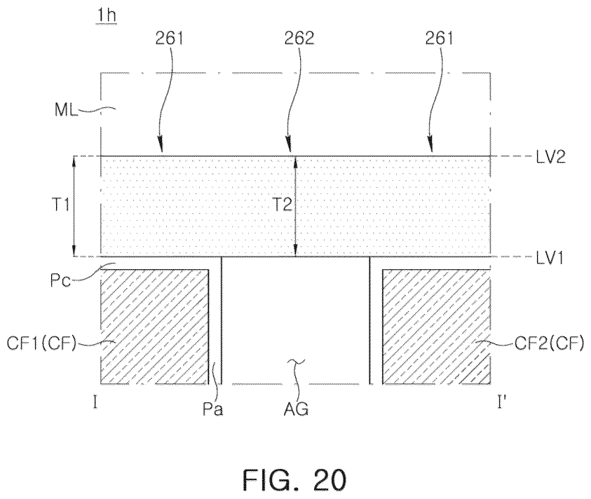

Referring to FIG. 20, the capping layer 260 of the image sensor 1h may include a first portion 261 that vertically overlaps the color filter CF and a second portion 262 disposed between two adjacent color filters CF. In one or more example embodiments, the thickness T2 of the second portion 262 may be equal to the thickness T1 of the first portion 261. For example, the lower and upper surfaces of the second portion 262 may be flat and may be located at the first vertical level LV1 and the second vertical level LV2, respectively.

As set forth above, according to one or more example embodiments, since the grid structure includes an air gap, optical cross talk sites may be prevented or reduced.

While one or more example embodiments have been particularly illustrated and described above, it will be apparent to those skilled in the art that modifications and variations in form and details may be made therein without departing from the spirit and scope of the following claims.

What is claimed is:

1. An image sensor comprising:
photoelectric conversion elements within a substrate;
a separation structure within the substrate and between the photoelectric conversion elements;
an insulating structure on the substrate and the separation structure;
a plurality of color filters on the insulating structure;
a grid structure comprising a lower horizontal structure disposed on the insulating structure and a vertical structure connected to the lower horizontal structure and covering a side surface of one of the plurality of color filters;
upper horizontal structures covering upper surfaces of the plurality of color filters; and
a capping layer covering the upper horizontal structures and the grid structure,
wherein the grid structure further comprises an air gap, and wherein the vertical structure, the lower horizontal structure, and the capping layer are all disposed around the air gap.

2. The image sensor of claim 1, wherein an upper limit of the air gap is defined by the capping layer.

3. The image sensor of claim 1, wherein the upper horizontal structures extend from the vertical structure of the grid structure.

4. The image sensor of claim 1, wherein the grid structure and the upper horizontal structures each have a thickness of about 3 nm to about 200 nm.

5. The image sensor of claim 1, wherein the plurality of color filters are spaced apart from each other.

6. The image sensor of claim 1, wherein the capping layer is spaced apart from the plurality of color filters with the upper horizontal structures interposed therebetween.

7. The image sensor of claim 1, wherein the capping layer comprises a material different from a material of the upper horizontal structures.

8. The image sensor of claim 1,
wherein the plurality of color filters comprise a first color filter and a second color filter adjacent to each other in a first horizontal direction,
wherein the capping layer comprises a first portion vertically overlapping the first color filter and a second portion between the first color filter and the second color filter, and
wherein the second portion defines an upper limit of the air gap.

9. The image sensor of claim 8, wherein at least a portion of a lower surface of the second portion is at a different level from a lower surface of the first portion.

10. The image sensor of claim 8, wherein at least a portion of an upper surface of the second portion is at a different level from an upper surface of the first portion.

11. The image sensor of claim 8, wherein a thickness of the second portion is greater than or equal to a thickness of the first portion.

12. The image sensor of claim 8, wherein a lower surface of the second portion is a convex surface or a concave surface.

13. The image sensor of claim 8,
wherein the plurality of color filters further comprise a third color filter adjacent to the second color filter in a second horizontal direction, intersecting the first horizontal direction,
wherein the capping layer further comprises a third portion disposed between the first color filter and the third color filter, and
wherein at least a portion of a lower surface of the third portion is at a different level from a lower surface of the second portion.

14. The image sensor of claim 13, wherein a thickness of the third portion is different from a thickness of the second portion.

15. The image sensor of claim 1, further comprising a planarization layer disposed on the capping layer.

16. An image sensor comprising:
photoelectric conversion elements within a substrate;
a separation structure within the substrate and between the photoelectric conversion elements;
an insulating structure on the substrate and the separation structure;
a plurality of color filters on the insulating structure;
a protective layer covering the insulating structure and the plurality of color filters; and
a capping layer covering the protective layer,
wherein a lower end of the capping layer is at a higher level than lower surfaces of the plurality of color filters, and
the protective layer and the capping layer define an air gap between the plurality of color filters.

17. The image sensor of claim 16, wherein the protective layer comprises lower horizontal structures disposed on the insulating structure, vertical structures extending from the lower horizontal structures and covering side surfaces of the plurality of color filters, and upper horizontal structures extending from the vertical structures and upper surfaces of the plurality of color filters.

18. The image sensor of claim 17, wherein in plan view, the plurality of color filters are respectively surrounded by the vertical structures.

19. The image sensor of claim 17, wherein in plan view, the air gap extends horizontally between the vertical structures.

20. An image sensor comprising:
a lower chip comprising a logic circuit; and
an upper chip on the lower chip, bonded to the lower chip,
wherein the upper chip comprises:
photoelectric conversion elements disposed within a substrate;
a separation structure disposed within the substrate and between the photoelectric conversion elements;
an insulating structure disposed on the substrate and the separation structure;
a plurality of color filters disposed on the insulating structure and spaced apart from each other;
a grid structure disposed between the plurality of color filters, the grid structure comprising a lower horizontal structure disposed on the insulating structure and a vertical structure connected to the lower horizontal structure and covering a side surface of one of the plurality of color filters;
upper horizontal structures covering upper surfaces of the plurality of color filters;
a capping layer covering the upper horizontal structures and the grid structure; and
a micro lens disposed on the capping layer,
wherein the grid structure comprises an air gap surrounded by the vertical structure, the lower horizontal structure, and the capping layer.
